(19) United States
(12) Patent Application Publication
(10) Pub. No.: US 2025/0233087 A1
(43) Pub. Date: Jul. 17, 2025

(54) SYSTEMS AND METHODS FOR EMBEDDING ELECTRONIC COMPONENTS IN SUBSTRATES

(71) Applicant: Advanced Micro Devices, Inc., Santa Clara, CA (US)

(72) Inventors: Arsalan Alam, Austin, TX (US); Rahul Agarwal, Santa Clara, CA (US); Chandra Sekhar Mandalapu, Fort Collins, CO (US); Sri Ranga Sai Boyapati, Austin, TX (US)

(73) Assignee: Advanced Micro Devices, Inc., Santa Clara, CA (US)

(21) Appl. No.: 17/865,355

(22) Filed: Jul. 14, 2022

(51) Int. Cl. H01L 23/64; H01L 21/48; H01L 23/13; H01L 23/498

(52) U.S. Cl. CPC H01L 23/642; H01L 21/4853; H01L 21/486; H01L 23/13; H01L 23/49827; H01L 23/49838

(57) ABSTRACT

A disclosed method can include (i) forming a cavity in a substrate core for a semiconductor device from a floor of the substrate core to a ceiling of the substrate core, (ii) bonding an electronic component to an element through a bonding layer to form an electronic component aggregation, (iii) disposing the electronic component aggregation within the cavity, and (iv) filling the cavity. Various other apparatuses, systems, and methods are also disclosed.

### BACKGROUND

Integrated passive devices are becoming more widely used. Yet, as discussed further below, integrated passive devices or other electronic components are not always used in ways that are fully optimized. Accordingly, and as will be described in greater detail below, the present disclosure discusses both problems and corresponding solutions related to integrated electronic components.

### BRIEF DESCRIPTION OF THE DRAWINGS

The accompanying drawings illustrate a number of exemplary implementations and are a part of the specification. Together with the following description, these drawings demonstrate and explain various principles of the instant disclosure.

FIG. 1 shows a flow diagram for an example method for embedding passives in substrates.

FIG. 2 shows a first portion of an illustrative workflow for embedding passives in substrates.

FIG. 3 shows a second portion of an illustrative workflow for embedding passives in substrates.

FIG. 4 shows an example workflow for bonding an electronic component to another electronic component.

FIG. 5 shows an example workflow for bonding an electronic component to a dummy substrate.

FIG. 6 shows a first portion of an illustrative workflow for embedding electronic components such as passives in substrates.

FIG. 7 shows a second portion of an illustrative workflow for embedding electronic components such as passives in substrates.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the instant disclosure covers all modifications, equivalents, and alternatives falling within the scope of the appended claims.

### DETAILED DESCRIPTION OF EXEMPLARY EMBODIMENTS

The present disclosure describes various methods for embedding electronic components such as passives in substrates. As indicated above, integrated passive devices can provide a variety of benefits, including lower thickness, thickness tolerances, lower equivalent series inductance, smaller variation in terms of temperature and voltage, and increased lifetime in comparison to standard multi-layer ceramic capacitors, for example. This application accordingly proposes various improved architectures for, and methods of manufacturing, embedded integrated electronic components and/or passives in substrate cores. As explained in greater detail below, embedding integrated electronic components within substrate cores can, among other benefits, provide various advantages from a signal integrity and/or power integrity analysis standpoint.

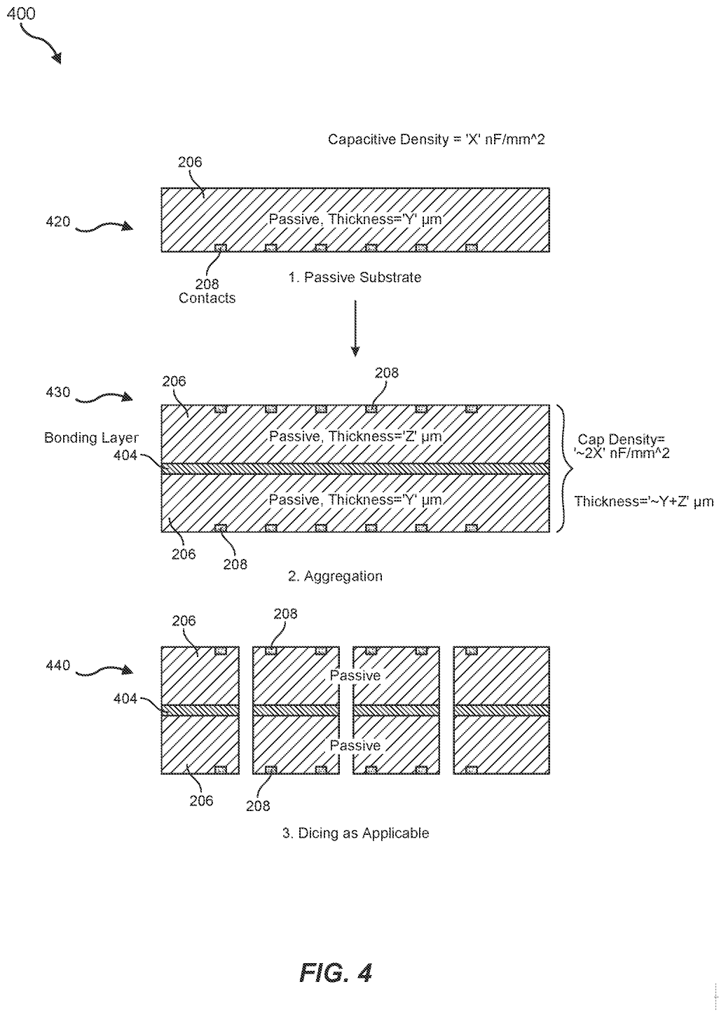

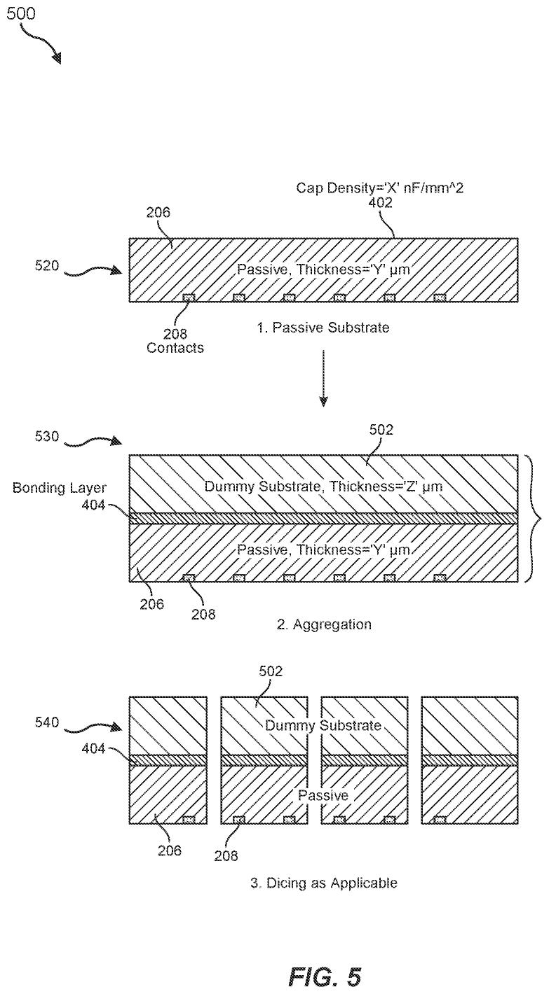

Generally speaking, the thickness of a substrate core between a top and bottom dielectric layer can be 800 microns or more, yet a traditional single silicon capacitor can be formed with a maximum thickness of approximately 775 microns, which can result in a height difference (e.g., 25 microns) that causes practical problems during manufacturing. Accordingly, usage of the technology of this application (as discussed further below in the context of FIGS. 4-5, for example) can increase the effective thickness of an embedded electronic component or aggregation, such that the 775 micron limitation is overcome and the overall thickness of the aggregation can substantially match the thickness of the substrate core. Moreover, the elimination or the substantial reduction of the height difference can help to prevent resulting voids and surface undulations that are undesirable and can degrade semiconductor performance.

As will be described in greater detail below, the instant disclosure generally relates to methods for embedding electronic components such as passives in substrates. In one example, such a method can include (i) forming a cavity in a substrate core for a semiconductor device from a floor of the substrate core to a ceiling of the substrate core, (ii) bonding an electronic component to an element through a bonding layer to form an electronic component aggregation, (iii) disposing the electronic component aggregation within the cavity, and (iv) filling the cavity. In this example, a thickness of the electronic component aggregation can substantially match a thickness of the substrate core.

In some examples, the element includes a dummy substrate.

In some examples, the element includes a second instance of the electronic component.

In some examples, bonding the electronic component to the second instance of the electronic component doubles a capacitance density of the semiconductor device in comparison to usage of a non-aggregated single-layer electronic component.

In some examples, the method further includes adding conductive contacts to an outward face of the electronic component opposite the element and adding conductive contacts to an outward face of the element opposite the electronic component.

In some examples, the electronic component includes a silicon capacitor.

In some examples, the electronic component has a maximum thickness of approximately 775 microns.

In some examples, the substrate core has a thickness greater than approximately 800 microns.

In some examples, a combined thickness of the electronic component and the element is greater than approximately 800 microns.

In some examples, a combined thickness of the electronic component and the element is less than or equal to approximately 1550 microns.

A corresponding semiconductor substrate can include an electronic component embedded within a cavity of a semiconductor substrate and an element bonded through a bonding layer to the electronic component to form an electronic component aggregation. In these examples, a thickness of the electronic component aggregation is substantially equal to a thickness of the semiconductor substrate.

Similarly, in some examples, a semiconductor device can include an electronic component embedded within a cavity of the semiconductor substrate and an element bonded through a bonding layer to the electronic component to form an electronic component aggregation. In these examples, a thickness of the electronic component aggregation is substantially equal to a thickness of a substrate core.

According to a first example architecture, integrated electronic components can be bonded back-to-back (see FIG. 4). This first architecture can provide a number of benefits, as explained below. For example, silicon capacitors are typically made on wafers that have a maximum thickness up to approximately 775 microns. Therefore, embedding silicon capacitors in the core of substrates that have a thickness of greater than 800 microns can become challenging. The first example architecture disclosed herein can thus increase a total silicon capacitor thickness and also increase a capacitance density, in terms of nanofarads per millimeter squared (nF/mm\hat{ }2). Additionally, a height of each silicon capacitor can be adjusted to provide a final desired thickness from approximately 775 microns up to approximately 1500 microns and greater, which might have been impossible with previous or related methodologies. The first architecture can also be used for embedding electronic components in substrate cores that have a thickness that is less than 800 microns.

According to a second example architecture (see FIG. 5), integrated electronic components or passives can be bonded with a dummy substrate to increase a total stack thickness from approximately 775 microns to up to approximately 1500 microns. This second architecture can be relatively simpler in configuration than the first architecture. Also, the second architecture does not necessarily achieve an increase or doubling of capacitance density.

The various implementations described herein can solve multiple problems and provide a variety of advantages. For example, the proposed implementations can allow the embedding of integrated electronic components, such as silicon capacitors, in substrate cores that have thicknesses greater than approximately 800 μm. Each electronic component can include an active component or a passive component, and can further include capacitors, inductors, and/or resistors, etc. In addition, the proposed implementations are not necessarily limited to providing core embedding solutions in the context of cores with thicknesses greater than 800 μm, but the proposed implementations can also be used with substrate cores having thicknesses less than 800 μm. For example, the first example architecture disclosed herein can provide an increase in capacitance density, in terms of nanofarads per millimeter squared (nF/mm\hat{ }2), by a factor of approximately two, while enabling integrated electronic component writing pads at both the top and the bottom of the stack, which can enable ease of routing, as discussed further below. In addition, the total thickness variation of the proposed stacked integrated electronic components can be less than a total thickness of a multi-layer ceramic capacitor with similar total thickness, thereby enabling easier embedding solutions. Additionally, the two back-to-back stacked capacitors can be used as individual capacitors. Accordingly, if one capacitor fails, the other capacitor in the stack can function as a KGD (“Known Good Die”) and provide benefits in terms of signal integrity and power integrity analyses.

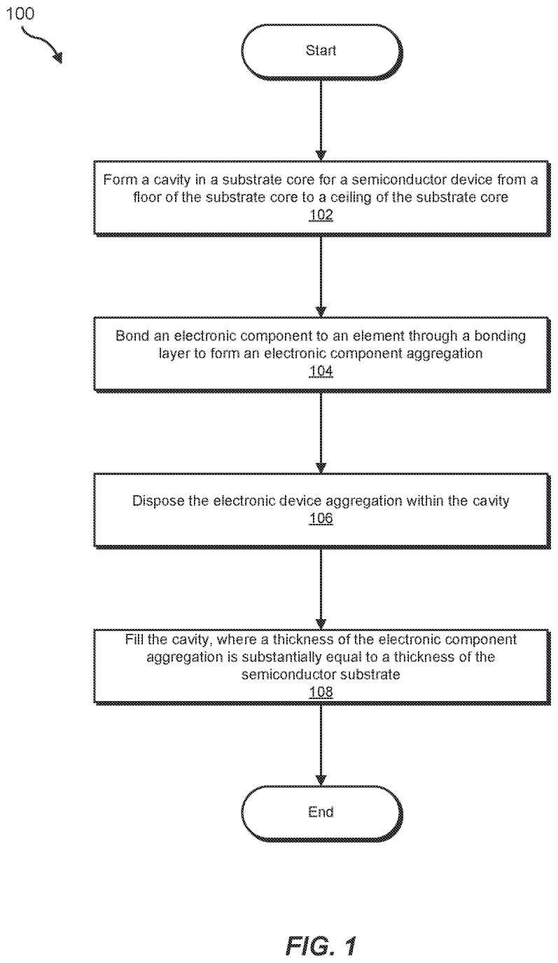

FIG. 1 shows a flow diagram of an example method 100 for embedding electronic components such as passives in substrates. As shown in this figure, at step 102, one or more of the apparatuses or systems described herein (e.g., a semiconductor device manufacturing facility) can form a cavity in a substrate core for a semiconductor device from a floor of the substrate core to a ceiling of the substrate core.

As used herein, a “substrate core” can refer to a primary substrate for creating a semiconductor device. Moreover, as used herein a “cavity” may refer to at least a partial hole or gap consistent with the figures herein, for example. Furthermore, as used herein, “floor” and “ceiling” may refer to the base and top, respectively, of the corresponding substrate, consistent the figures herein, for example.

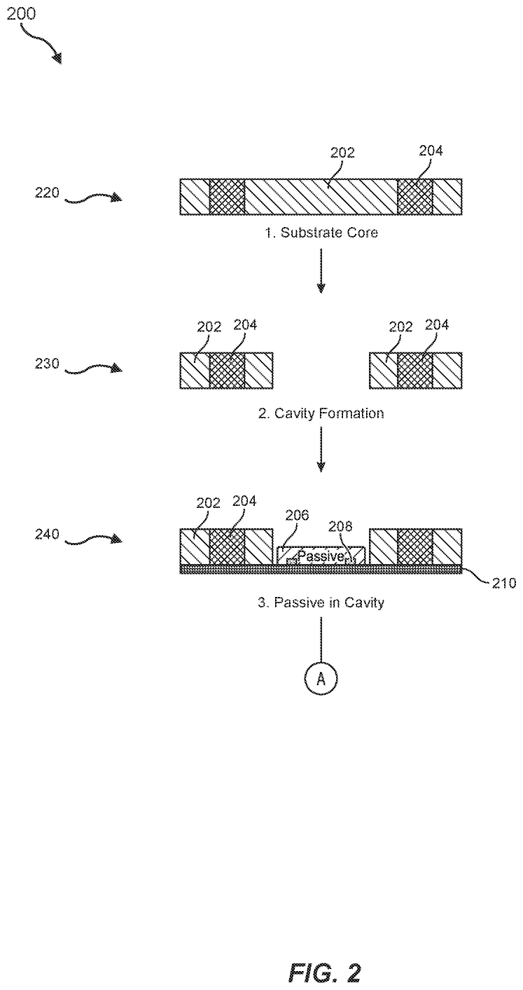

Step 102 can be performed in a variety of ways, as further discussed below in the context of FIGS. 2-3 and FIGS. 6-7. FIG. 2 shows an illustrative workflow 200, which can further include a workflow step 220, a workflow step 230, and a workflow step 240. Optionally, at workflow step 220, a substrate core can be formed of one or more materials. In this illustrative example, the substrate core can be formed of a first material 202 and a second material 204. The first material and the second material can be dielectrics or insulators, for example. In some examples, one of these materials forms a substantially uniform layer, in which one or more cavities for the insertion of the other of these materials can be inserted. For example, cavities can be formed within a substantially uniform layer of first material 202, thereby providing room for insertion of second material 204. Illustrative examples of such materials can include pre-preg and Ajinomoto Build-up Film.

As further shown in FIG. 2, at workflow step 230, a cavity can be formed within the substrate core corresponding to workflow step 220. This particular cavity can be formed for the purpose of insertion of an electronic component. As further shown in this figure, the cavity can be formed from a ceiling (e.g., topmost point) of the substrate core to a floor (e.g., bottommost point) of the substrate core.

At workflow step 240, an electronic component such as a capacitor can be inserted within the cavity that was previously formed at workflow step 230. The electronic component can be formed substantially of a passive material 206, which can be electrically connected to an exterior through one or more conductive contacts 208. Conductive contacts 208 can be formed of copper, for example, or any other suitable conductive material. At workflow step 240, a substrate core floor layer 210 can also be disposed beneath a remainder of the substrate core including the electronic component inserted within the cavity formed at workflow step 230.

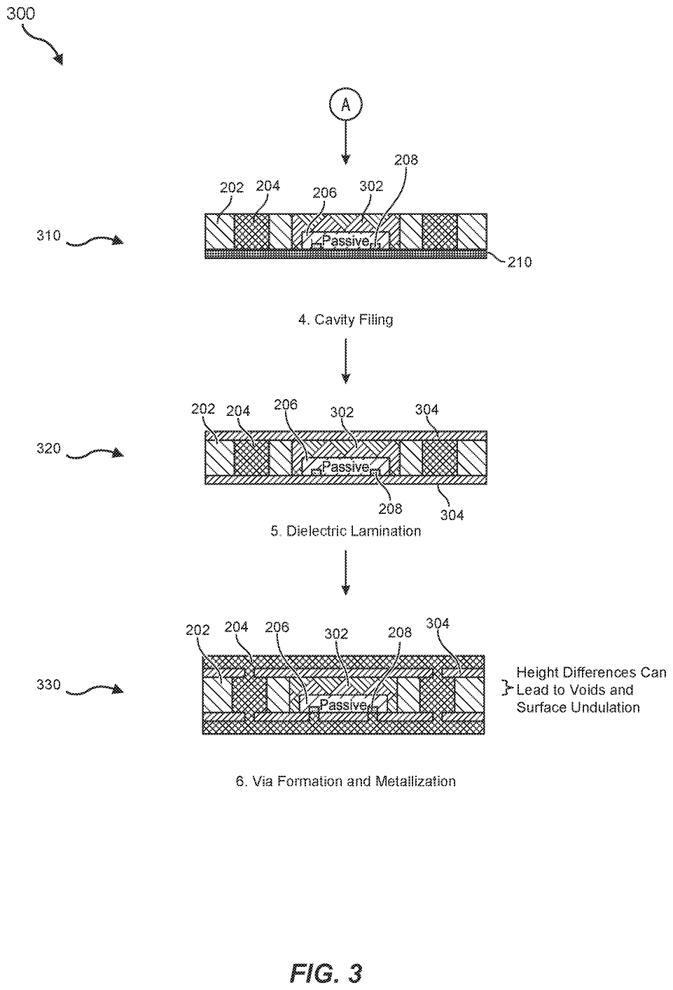

From FIG. 2, workflow 200 can continue in the form of a workflow 300 shown in FIG. 3, which can include a workflow step 310, a workflow step 320, and a workflow step 330. At workflow step 310, the cavity that was previously created at workflow step 220 can be filled with an appropriate dielectric or insulating material 302. One illustrative example of such material can include Ajinomoto Build-up Film. More generally, material 302 can include a dielectric material with a relatively low dielectric constant and/or desirable or appropriate fluidity, such as resin-based materials having a relatively low dielectric constant and/or a desirable degree of fluidity.

At workflow step 320, a dielectric layer 304 can be laminated to a top of the substrate core. A corresponding and parallel dielectric layer 304 can also be laminated to a bottom of the substrate core, thereby replacing substrate core floor layer 210.

Lastly, at workflow step 330, vias such as plated through-holes can be formed and a metallization process can be performed. In particular, cavities within the dielectric layer 304 at the top and the bottom of the substrate core shown at workflow step 320 can be formed, at workflow step 330, thereby enabling electrical contacts to be connected through these specific cavities in the dielectric layer. For example, conductive contacts 208 can be electrically connected to an exterior through the cavities formed within dielectric layer 304 on the bottom of the substrate core.

Workflow step 330 as shown in FIG. 3 also further illustrates how the height or thickness of the electronic component is substantially shorter or smaller than the substrate core between the top instance of dielectric layer 304 and the bottom instance of dielectric layer 304. As further highlighted in this figure, this particular height difference can lead to performance problems for the corresponding semiconductor device. In particular, the height difference can lead to voids within the substrate core. For example, despite the cavity filling procedure of workflow step 310, as further discussed above, one or more voids can form above or adjacent to the electronic component that has been embedded within the substrate core. Additionally, or alternatively, the height difference outlined at workflow step 330 of FIG. 3 can also potentially cause surface undulation, which can also be undesirable and/or cause additional performance problems. In some examples, the surface undulation can be caused by the forming of one or more voids beneath a corresponding surface, as further discussed above.

Returning to FIG. 1, at step 104, one or more of the apparatuses or systems described herein (e.g., a semiconductor device manufacturing facility) can bond an electronic component to an element through a bonding layer to form an electronic component aggregation. As used herein, the phrase “bond” may refer to connecting, sticking, or adhering together, for example. Moreover, as used herein, the term “electronic component aggregation” generally refers to an aggregation formed by bonding an element to a surface of an electronic component, as further discussed below. Furthermore, as used herein, the term “element” generically refers to items that can be bonded along a surface to the electronic component discussed above, and such elements may include active electronic components, passive electronic components, and/or dummy substrates as further discussed below.

Step 104 can be performed in a variety of ways. FIG. 4 and FIG. 5 show illustrative examples of the performance of step 104, which can help to overcome the problems associated with the height difference that was highlighted at workflow step 330 of FIG. 3, as further discussed above.

FIG. 4 shows an illustrative example of a workflow 400, which can correspond to a procedure for the performance of one implementation of step 104. Workflow 400 can further include a workflow step 420, a workflow step 430, and a workflow step 440. As further shown at workflow step 420, a substrate, which can be formed substantially of a passive material 206 (see FIG. 2), can be formed or obtained. The substrate at workflow step 420 can also have a number of conductive contacts 208 embedded appropriately on one surface, such as a bottom surface of the substrate. Workflow step 420 also further highlights how the substrate can have a thickness of Y microns, as well as a capacitive density X in terms of nanofarads per millimeter squared.

At workflow step 430, which can correspond to an aggregation step, a second instance of the substrate can be bonded, along a bonding surface, to the substrate of workflow step 420. In this particular example, a thickness of the top substrate can substantially match a thickness of the bottom substrate. Workflow step 430 also highlights how the second instance of the substrate can have a thickness of Z microns. The original substrate of workflow step 420 and the additional substrate of workflow step 430 can be bonded together through a bonding layer 404. Bonding layer 404 can be formed of any appropriate resin or adhesive, for example. Moreover, just as the original substrate of workflow step 420 had a number of conductive contacts 208 disposed on an exterior surface opposite the bonding surface, so too the additional substrate of workflow step 430 can also have a number of conductive contacts 208 disposed on an exterior surface opposite the bonding surface.

Workflow step 430 also further highlights how the bonding of the original substrate and the second instance of the substrate together through bonding layer 404 can effectively improve the values discussed above. In particular, the capacitance density X of workflow step 420 has been effectively or approximately doubled to 2X. In other words, bonding the electronic component to the second instance of the electronic component doubles a capacitance density of the semiconductor device in comparison to usage of a non-aggregated single-layer electronic component. This effective doubling of the capacitance density measurement is due to the fact that the number of substrate components (e.g., capacitors) has been doubled by placing two instances of the substrate components on the same amount of substrate core real estate (e.g., back-to-back or on top of each other). Additionally, the original thickness Y of the substrate at workflow step 420 has been increased to a combined thickness Y +Z in microns, where Z is the thickness of the second instance of the substrate. Thus, in the example where Z is substantially the same as Y, then the bonding of the original substrate and the second instance of the substrate can effectively double the thickness of the substrate aggregation. In other examples, however, any suitable thickness for the second instance of the substrate can be used. In other words, although the thickness of the original substrate and the second instance of the substrate appear to be substantially the same in FIG. 4, this example is merely illustrative, and in other examples the original substrate and the second instance of the substrate can have different or substantially different thicknesses.

At workflow step 440, a dicing procedure can be performed on the aggregation of the original substrate and the second instance of the substrate that were combined at workflow step 430. Accordingly, workflow step 440 illustrates how the aggregation of workflow step 430 can be diced or separated into a plurality of different subdivisions.

Whereas FIG. 4 shows a workflow 400 that corresponded to the first architecture of this application, as further discussed above, FIG. 5 shows a workflow 500 that corresponds to the second architecture. Workflow 500 can include a workflow step 520, a workflow step 530, and a workflow step 540. Workflow 500 can substantially parallel workflow 400, with the exception that, at workflow step 530 (parallel to workflow step 430), an instance of a dummy substrate 502 can be bonded to the original substrate of workflow step 520, rather than using a second instance of the substrate, as in FIG. 4. As a dummy substrate, this particular substrate can be formed of any suitable material, including any suitable dielectric or insulating material, but without necessarily possessing the electrodynamic properties of the substrate, such as capacitance.

As further illustrated in FIG. 5, substrate 502 can have a height or thickness Z, just as the second instance of the substrate in FIG. 4 had a height or thickness Z. Thus, in parallel, the bonding of dummy substrate 502 to the substrate at workflow step 530 can effectively increase the overall height or thickness of the aggregation to Z+Y, as in workflow 400. In contrast, however, dummy substrate 502 might not necessarily have the electrodynamic properties of the substrate, such as capacitance, and therefore the second architecture corresponding to workflow 500 might not necessarily double the capacitance density, as was achieved with the first architecture described above in connection with FIG. 4.

Returning to FIG. 1, at step 106 one or more of the systems described herein (e.g., a semiconductor device manufacturing facility) can dispose the electronic component aggregation within the cavity. Similarly, at step 108, one or more of the systems described herein can fill the cavity. As used herein, the phrase “dispose” generally refers to placing or embedding, for example.

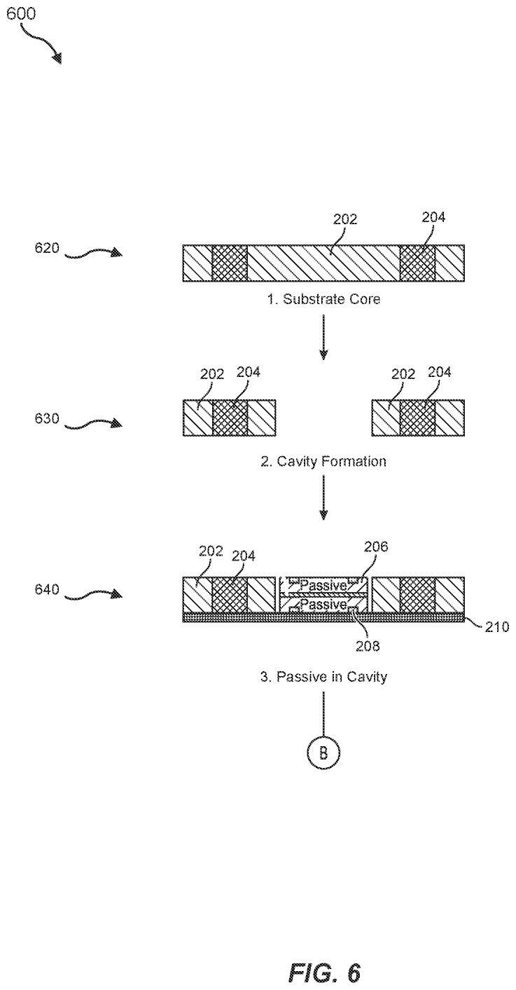

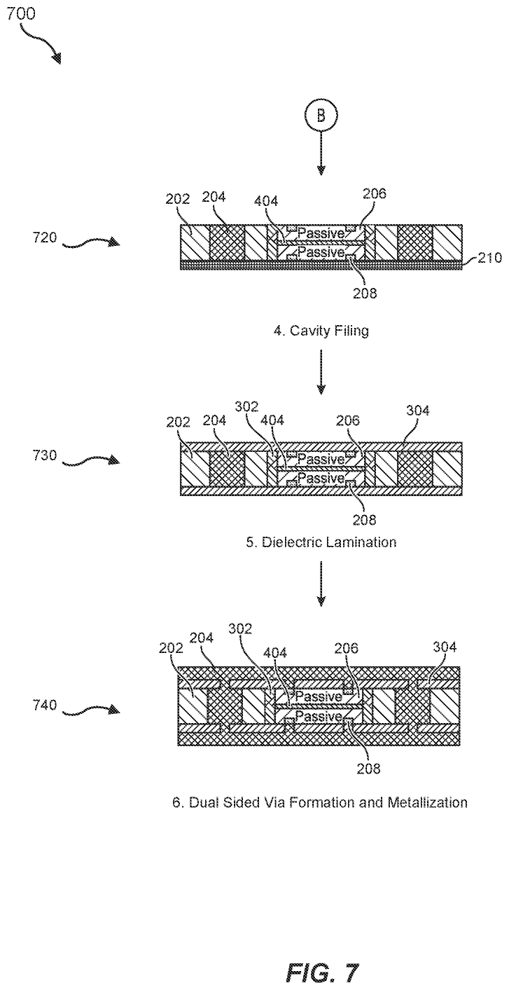

Steps 106-108 can be performed in a variety of ways. After the performance of step 104, in which the original substrate has been bonded to an element according to the first architecture of FIG. 4 or the second architecture of FIG. 5, the resulting electronic component aggregation can be disposed within the cavity and then the cavity can be filled. FIGS. 7-8 show an illustrative workflow 700 and an illustrative workflow 800, which can include the performance of steps 106-108 in the context of the first architecture. The same steps can be effectively performed in a parallel manner in the context of the second architecture (which is not necessarily shown in FIGS. 6-7).

FIGS. 6-7 can substantially parallel workflow 200 and workflow 300 of FIGS. 2-3, except that a workflow 600 and a workflow 700 of FIGS. 6-7 effectively eliminate, or substantially reduce, the undesirable height difference that was highlighted by workflow step 330. By using the electronic component aggregation (e.g., the electronic component aggregation of FIG. 4 or FIG. 5), which can have a thickness (i.e., due to the bonding or aggregation) that is substantially greater than the corresponding thickness of the substrate at workflow step 330, the undesirable height difference can be eliminated, as further discussed below.

Workflow 600 can include a workflow step 620, a workflow step 630, and a workflow step 640, which can substantially parallel workflow step 220, workflow step 230, and workflow step 240, respectively. As further shown in FIG. 6, beginning with a substrate core at workflow step 620, a cavity can be formed at workflow step 630 from the floor of the substrate core to a ceiling of the substrate core. At workflow step 640, the electronic component aggregation corresponding to the first architecture of FIG. 4 can be inserted within the cavity that was formed at workflow step 630. Accordingly, workflow step 640 can correspond to step 106 of method 100. The electronic component aggregation can be formed of passive material 206 and can include conductive contacts 208, as further illustrated in this figure. Additionally, at workflow step 640, substrate core floor layer 210 can also be disposed beneath a remainder of the substrate core including the electronic component aggregation inserted within the cavity formed at workflow step 630.

FIG. 7 shows an illustrative workflow 700, which can further include a workflow step 720, a workflow step 730, and a workflow step 740. Workflow step 720, workflow step 730, and workflow step 740 can substantially parallel workflow step 310, workflow step 320, and workflow step 330, with the exception that the height difference highlighted at workflow step 330 can be eliminated or substantially reduced due to the use of the electronic component aggregation discussed above in connection with FIGS. 4-5.

At workflow step 720, a cavity filling operation can be performed, which can further correspond to step 108 of method 100. Accordingly, the one or more gaps between the inserted electronic component aggregation and the substrate that remains after the creation of the cavity at workflow step 630 can be filled with an appropriate material, such as a resin, dielectric, and/or insulating material. At workflow step 730, a dielectric layer 304 can be laminated to a top of the substrate core and another instance of dielectric layer 304 can be laminated to a bottom of the substrate core. Lastly, at workflow step 740, vias such as plated through-holes can be formed, and a metallization procedure can be performed, in a dual-sided manner (e.g., top and bottom sides of the substrate core), thereby electrically connecting or exposing the conductive contacts 208 for both the bottom-side electronic component as well as for the top-side second instance of the electronic component, as further shown in this figure.

With respect to workflow step 740, the thickness of the substrate core between dielectric layer 304 at the top and dielectric layer 304 at the bottom can be 800 microns or more, yet a traditional single silicon capacitor can be formed with the maximum thickness of approximately 775 microns. Accordingly, usage of the electronic component aggregation corresponding to FIGS. 4-5, for example, can increase the effective thickness of the electronic component aggregation, such that the 775 micron limitation is overcome and the overall thickness of the electronic component aggregation can substantially match the thickness of the substrate core. Moreover, the elimination or the substantial reduction of the height difference can help to prevent the resulting voids and surface undulations that are undesirable and can degrade semiconductor performance, as further discussed above.

Various implementations are described herein with sufficient detail to enable one skilled in the art to practice the disclosure. It is understood that the various implementations of the disclosure, although different, are not necessarily exclusive and can be combined differently because they show novel features. For example, a particular feature, structure, step of manufacturing, or characteristic described in connection with one implementation can be implemented within other implementations without departing from the spirit and scope of the disclosure. In addition, it is understood that the location and arrangement of individual elements, such as geometrical parameters within each disclosed implementation, can be modified without departing from the spirit and scope of the disclosure. Other variations will also be recognized by one of ordinary skill in the art. The following detailed description is, therefore, not to be taken in a necessarily limiting sense.

As further outlined above, the various implementations described herein can solve multiple problems and provide various advantages. For example, the proposed implementations can allow the embedding of integrated electronic components, such as passive devices including silicon capacitors, in substrate cores that have thicknesses greater than approximately 800 μm. In addition, the proposed implementations might not be limited to providing core embedding solutions in the context of cores with thicknesses greater than 800 μm, but the proposed implementations can also be used with substrate cores having thicknesses less than 800 μm. The first example architecture can also provide an increase of capacitance density, in terms of nanofarads per millimeter squared (nF/mm\hat{ }2), by a factor of approximately two, while enabling integrated electronic component routing pads at both the top and the bottom of the stack, which can help with enabling ease of routing. In addition, a total thickness variation of the proposed stacked integrated electronic components can be less than a total thickness of a multi-layer ceramic capacitor with similar total thickness, thereby enabling easier embedding solutions. Additionally, the two back-to-back stacked capacitors can be used as individual capacitors. Accordingly, if one capacitor fails, the other capacitor in the stack can function as a KGD (“Known Good Die”) and provide benefits in terms of signal integrity and power integrity analyses.

For completeness, the above discussion relates to semiconductor devices including computer processors. Such processors can include and/or represent any type or form of hardware-Implemented device capable of interpreting and/or executing computer-readable instructions. In one example, the processor can include and/or represent one or more semiconductor devices implemented and/or deployed as part of a computing system. One example of the processor includes central processing units (CPUs) and microprocessors. Other examples, depending on context, can include microcontrollers, field-programmable gate arrays (FPGAs) that implement softcore processors, application-specific integrated circuits (ASICs), systems on a chip (SoCs), portions of one or more of the same, variations or combinations of one or more of the same, and/or any other suitable processor.

The processor can implement and/or be configured with any of a variety of different architectures and/or microarchitectures. For example, the processor can implement and/or be configured as a reduced instruction set computer (RISC) architecture or the processor can implement and/or be configured as a complex instruction set computer (CISC) architecture. Additional examples of such architectures and/or microarchitectures include, without limitation, 16-bit computer architectures, 32-bit computer architectures, 64-bit computer architectures, x86 computer architectures, advanced RISC machine (ARM) architectures, microprocessor without interlocked pipelined stages (MIPS) architectures, scalable processor architectures (SPARCs), load-store architectures, portions of one or more of the same, combinations or variations of one or more of the same, and/or any other suitable architectures or microarchitectures.

In some examples, the processor can include and/or incorporate one or more additional components that are not explicitly represented and/or illustrated in the figures. Examples of such additional components include, without limitation, registers, memory devices, circuitry, transistors, resistors, capacitors, diodes, connections, traces, buses, semiconductor (e.g., silicon) devices and/or structures, combinations or variations of one or more of the same, and/or any other suitable components.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered exemplary in nature since many other architectures can be implemented to achieve the same functionality.

The apparatuses, systems, and methods described herein can employ any number of software, firmware, and/or hardware configurations. For example, one or more of the exemplary implementations disclosed herein can be encoded as a computer program (also referred to as computer software, software applications, computer-readable instructions, and/or computer control logic) on a computer-readable medium. The term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives and floppy disks), optical-storage media (e.g., Compact Disks (CDs) and Digital Video Disks (DVDs)), electronic-storage media (e.g., solid-state drives and flash media), and/or other distribution systems.

In addition, one or more of the modules, instructions, and/or micro-operations described herein can transform data, physical devices, and/or representations of physical devices from one form to another. Additionally or alternatively, one or more of the modules, instructions, and/or micro-operations described herein can transform a processor, volatile memory, non-volatile memory, and/or any other portion of a physical computing device from one form to another by executing on the computing device, storing data on the computing device, and/or otherwise interacting with the computing device.

The process parameters and sequence of the steps described and/or illustrated herein are given by way of example only and can be varied as desired. For example, while the steps illustrated and/or described herein can be shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the instant disclosure. The implementations disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A method comprising:
forming a cavity in a substrate core for a semiconductor device from a floor of the substrate core to a ceiling of the substrate core;
bonding an electronic component to an element through a bonding layer to form an electronic component aggregation;
disposing the electronic component aggregation within the cavity; and
filling the cavity;
wherein a thickness of the electronic component aggregation substantially matches a thickness of the substrate core.

2. The method of claim 1, wherein the element comprises a dummy substrate.

3. The method of claim 1, wherein the element comprises a second instance of the electronic component.

4. The method of claim 3, wherein bonding the electronic component to the second instance of the electronic component doubles a capacitance density of the semiconductor device in comparison to usage of a non-aggregated single-layer electronic component.

5. The method of claim 4, further comprising:
adding conductive contacts to an outward face of the electronic component opposite the element; and
adding conductive contacts to an outward face of the element opposite the electronic component.

6. The method of claim 1, wherein the electronic component comprises a silicon capacitor.

7. The method of claim 1, wherein the electronic component has a maximum thickness of approximately 775 microns.

8. The method of claim 1, wherein the substrate core has a thickness greater than approximately 800 microns.

9. The method of claim 8, wherein a combined thickness of the electronic component and the element is greater than approximately 800 microns.

10. The method of claim 8, wherein a combined thickness of the electronic component and the element is less than or equal to approximately 1550 microns.

11. A semiconductor substrate comprising:
an electronic component embedded within a cavity of the semiconductor substrate; and
an element bonded through a bonding layer to the electronic component to form an electronic component aggregation;
wherein a thickness of the electronic component aggregation is substantially equal to a thickness of the semiconductor substrate.

12. The semiconductor substrate of claim 11, wherein the element comprises a dummy substrate.

13. The semiconductor substrate of claim 11, wherein the element comprises a second instance of the electronic component.

14. The semiconductor substrate of claim 13, wherein bonding the electronic component to the second instance of the electronic component doubles a capacitance density of a corresponding semiconductor device in comparison to usage of a non-aggregated single-layer electronic component.

15. The semiconductor substrate of claim 14, wherein:
conductive contacts are disposed on an outward face of the electronic component opposite the element; and
conductive contacts are disposed on an outward face of the element opposite the electronic component.

16. The semiconductor substrate of claim 11, wherein the electronic component comprises a silicon capacitor.

17. The semiconductor substrate of claim 11, wherein the electronic component has a maximum thickness of approximately 775 microns.

18. The semiconductor substrate of claim 11, wherein a substrate core has a thickness greater than approximately 800 microns.

19. The semiconductor substrate of claim 18, wherein a combined thickness of the electronic component and the element is greater than approximately 800 microns.

20. A semiconductor device comprising:
an electronic component embedded within a cavity of a semiconductor substrate; and
an element bonded through a bonding layer to the electronic component to form an electronic component aggregation;
wherein a thickness of the electronic component aggregation is substantially equal to a thickness of the semiconductor substrate.
